(19) United States
(12) Patent Application Publication
(10) Pub. No.: US 2008/0251920 A1
(43) Pub. Date: Oct. 16, 2008

(54) Dielectric film forming method

(75) Inventor: Shigeo Ishikawa, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 11/882,016

(22) Filed: Jul. 30, 2007

(30) Foreign Application Priority Data
Jul. 31, 2006 (JP) 2006-207432

(51) Int. Cl. H01L 23/52; H01L 21/31

(52) U.S. Cl. 257/751; 438/778; 257/E21.249; 257/E23.141

(57) ABSTRACT

In a film forming sequence for a HDP-CVD oxide film, Ar gas is introduced into a reactive chamber and then source power (or RF power) is applied to excite plasma. After that, a carrier gas (He) is introduced into the reactive chamber. After a semiconductor substrate is heated by plasma of the Ar and He gasses, introduction of the Ar gas is stopped. Subsequently, SiH₄ and O₂ gasses are simultaneously introduced into the reactive chamber and bias power is applied with ramping. Because the O₂ gas is not introduced into the reactive chamber before the beginning of the film formation, oxidization of a W wiring line is suppressed.

This application is based upon and claims the benefit of priority from Japanese patent application No. 2006-207432, filed on Jul. 31, 2006, the disclosure of which is incorporated herein in its entirety by reference.

### BACKGROUND OF THE INVENTION

This invention relates to a dielectric film manufacturing method, in particular, to a dielectric film manufacturing method for manufacturing a dielectric film including oxygen by a plasma chemical vapor deposition (CVD).

Recently, a semiconductor device is integrated in a large scale and its chip size is large. When the chip size is large, length of a wiring line in the semiconductor device is long and thereby the wiring line has a high electric wiring resistance. The high electric wiring resistance of the wiring line makes delay time of the wiring line large. As a result, the semiconductor device can not operate at high speed. Therefore, a low resistance wiring line is required for the large scale semiconductor device. Generally, the semiconductor device has a plurality of wiring layers. For the wiring layers, various metal wiring lines are used as the low resistance wiring lines.

In a case where a metal wiring line is exposed to high temperature heat treatment after its formation, high melting point metal, high melting point metal silicide, high melting point metal polycide or the like is used for the metal wiring line. On the other hand, in a case where the metal wiring line is not exposed to the high temperature heat treatment, aluminum, copper or their alloy is used for the metal wiring line. Metal wiring lines are isolated by an interlayer dielectric film which is formed after formation of the metal wiring lines. The interlayer dielectric film is generally formed by a plasma CVD method. Especially, a high density plasma chemical vapor deposition (HDP-CVD) method is more commonly used by reason that it can form a thick film in good coating condition.

For example, in a large scale memory, because gate wiring lines and bit wiring lines are exposed to high temperature heat treatment after their formation, tungsten (W) which is high melting metal is used for the wiring lines. However, the tungsten is easy to be oxidized in oxygen environment. An oxidized tungsten wiring line causes a problem that its electric resistance becomes high. Furthermore, oxidized tungsten wiring line causes another problem that its adhesive deteriorates and that it is peeled off. To inhibit the oxidation of the tungsten wiring line, a silicon nitride (Si₃N₄) film is used. However, use of the silicon nitride film cause another problem that the electric wiring resistance of the wiring line increases by about 30 percents as compared with a case where the silicon nitride film is not used. Accordingly, it is necessary to increase thickness of the tungsten wiring line and thus there is a problem that miniaturization is impossible.

The problems mentioned above are described in more detail with reference to FIGS. 1 to 5.

FIG. 1 shows measured values of electric wiring resistance of wiring lines with oxidation inhibitor (Si₃N₄) films and those of other wiring lines without the oxidation inhibitor films. FIG. 2 is a schematic diagram of a transmission electron microscope (TEM) image of an oxidized tungsten wiring line. FIG. 3 is a schematic diagram of a TEM image of a tungsten wiring line covered with an oxidation inhibitor (Si₃N₄) film. FIGS. 4A-4C are longitudinal sectional views for describing manufacturing steps of bit wiring lines of a related semiconductor device. FIG. 5 shows film forming sequence of a related HDP-CVD method.

Referring to FIG. 4A-4C, the manufacturing steps of the bit wiring lines of the related semiconductor device will be described.

In FIG. 4A, a tungsten nitride (WN) film 1 and a tungsten (W) film 2 are formed in this order and they are etched to form desired tungsten wiring lines 3. In this specification, the wiring lines each of which are made of the WN film 1 and the W film 2, are collectively referred to as W wiring lines 3.

On top surfaces of the W wiring lines 3, hard masks, e.g. Si₃N₄ film masks 4, which are used for the etching of the WN film 1 and the W film 2, remains. On the other hand, side surfaces of the W wiring lines 3 are exposed. If an oxide film is formed to isolate the W wiring lines 3 from one another by the HDP-CVD method, it is in contact with the side surfaces of the W wiring lines 3. As a result, the side surfaces of the W wiring lines are oxidized. By oxidization of the side surfaces of the W wiring lines 3, problems, such as a wiring resistance defect, occurrence of peeling off and so on, are caused.

Therefore, as illustrated in FIG. 4B, to inhibit the side surfaces of the wiring lines 3 from being oxidized, an oxidation inhibitor film, e.g. an Si₃N₄ film oxidization inhibitor 5 having a thickness of about 3-10 nm, is formed on the whole of an upper side of a semiconductor substrate on which the W wiring lines 3 are formed. The Si₃N₄ film oxidization inhibitor 5 may be etched back to remove the Si₃N₄ film oxidization inhibitor 5 on the upper surface of the semiconductor substrate. In such a case, the top surfaces of the W wiring line 3 is covered with the Si₃N₄ film masks 4 while the side surfaces of the W wiring line 3 is covered with the Si₃N₄ film oxidation inhibitor 5.

Subsequently, as illustrated in FIG. 4C, an HDP-CVD oxide film 6 is formed. The oxide film 6 is formed by the HDP-CVD method. FIG. 5 shows the sequence of the film forming process according to the HDP-CVD method.

It is general to use silane (SiH₄) and gaseous oxygen (O₂) as reactive gasses, and helium (He) and argon (Ar) as carrier gasses. In the sequence of the HDP-CVD method, first, Ar gas is introduced into a reaction chamber and then RF power is impressed thereto as source power to generate plasma. After that, O₂ gas and carrier gas (He) are sequentially introduced into the reaction chamber. After a substrate is heated by plasma of Ar, O₂ and He, introduction of Ar gas is stopped. Then, SiH₄ gas is introduced into the reaction chamber while bias power is impressed with ramping. Thus, the oxide film is formed.

When the Si₃N₄ film is used as the oxidation inhibitor for the W wiring lines 3, there is the problem that the electric wiring resistance of the W wiring lines 3 is increased by 30 percents in comparison with a case where the Si₃N₄ is not used, as shown in FIG. 1. To reduce the electric wiring resistance of the W wiring lines, it is necessary to increase thickness of the W wiring lines. Accordingly, miniaturization is impossible.

FIG. 3 is the schematic diagram of the TEM image of the tungsten wiring line covered with the oxidation inhibitor (Si₃N₄) film. As shown in FIG. 3, the W wiring line 3 is made of the WN film 1 and the W film 2 and the Si₃N₄ film mask 4 is provided on the top surface thereof. After the Si₃N₄ film oxidation inhibitor 5 is formed on the whole of the upper side of the semiconductor substrate, the HDP-CVD oxide film 6 is formed. Because the W wiring lines 3 are covered with the Si₃N₄ film oxidation inhibitor 5, oxidization thereof is prevented when the HDP-CVD oxide film 6 is formed.

To the contrary, the W wiring lines 3 are oxidized, if the HDP-CVD oxide film 6 is formed on the patterned W wiring lines 3 directly. FIG. 2 is the schematic diagram of the TEM image of the oxidized W wiring line 3. As shown in FIG. 2, the W wiring lines 3 made of the WN film 1 and the W film 2 and the Si₃N₄ film mask 4 is provided on the top surface thereof. The HDP-CVD oxide film 6 is formed on the W wiring lines 3 directly. When the HDP-CVD oxide film 6 is formed on the patterned W wiring lines 3 directly, the side surfaces of the W wiring lines 3 are oxidized and thereby W oxide 7 is formed. Though both of the WN film 1 and the W film 2 are oxidized, their oxides are not distinguished from each other here and they are referred to as the W oxide 7.

As mentioned above, the W wiring lines 3 are oxidized when the HDP-CVD oxide film 6 is formed on the patterned W wiring lines 3 directly. Then, the width of each W wiring line 3 is increased by about two times. The widths of the W wiring lines 3 are considerably increased and thereby reducing intervals between the W wiring lines 3. Therefore, it is hard to form a via between the W wiring lines 3. Furthermore, the oxidation of the W wiring line increases the electric wring resistance and deteriorates adhesion of the W wiring line and thereby causing peeling off.

Regarding plasma CVD, patent documents as mentioned below are known. Japanese patent laid-open publication No. 305236 (2002) disclosed a plasma device which heats a semiconductor substrate by plasma, and then transfers the semiconductor substrate to a susceptor for film forming to treat. Japanese patent laid-open publication No. 84888 (1994) discloses a dielectric film forming method which forms a dielectric film having good film quality by introducing organic silane gas into a chamber in condition that oxidizing gas is introduced in the chamber and that plasma discharge is generated.

These documents are not aware of the problems solved by the present invention. Film forming sequences disclosed in these documents are quite different from that of the present invention.

### SUMMARY OF THE INVENTION

As mentioned above, in a semiconductor device, various metal wiring lines are used. High melting point metal such as W is used as a material of a metal wiring line to which high temperature heat treatment is applied. However, it is a problem that the W wiring line is oxidized when an oxide film is formed on the W wiring line directly. In addition, use of a Si₃N₄ film to inhibit the W wiring line from being oxidized causes another problem of increase of electronic wiring resistance.

Therefore, in view of the problems, an object of this invention is to provide a dielectric film forming method capable of forming a dielectric film including oxygen without both formation of an oxidization inhibitor film and oxidization of the W wiring line.

To solve the problem mentioned above, this invention basically employs technique mentioned below. Various modifications are possible in the scope of the present invention and such an applied technology is included in this invention.

According to a first aspect of this invention, a film forming method is for forming a dielectric film including oxygen by a plasma chemical vapor deposition method. The method includes the step of forming the dielectric film on a metal wiring line formed on a semiconductor substrate in a reactive chamber. Gas including the oxygen is not introduced into the reactive chamber before the forming step.

The method may include the steps of introducing a carrier gas into the reactive chamber before the forming step; applying source power to the carrier gas to generate plasma and to heat the semiconductor substrate by the plasma; introducing silane and oxygen into the reactive chamber as source gasses for the dielectric film after the applying step of the source power; and applying bias power to the source gasses to execute the forming step.

According to a second aspect of this invention, a semiconductor device includes a metal wiring line formed on a semiconductor substrate and a dielectric film including oxygen formed on the metal wiring line. The dielectric film is formed in a reactive chamber by a plasma chemical vapor deposition method. Gas including the oxygen is not introduced into the reactive chamber before formation of the dielectric film.

wiring line comprises high melting point metal.

According to a third aspect of this invention, a film forming method is for forming a dielectric film including oxygen by plasma chemical vapor deposition method. The method includes the step of forming the dielectric film on a metal wiring line formed on a semiconductor substrate in a reactive chamber. Introduction of gas including the oxygen into the reactive chamber is started to start the forming step.

### BRIEF DESCRIPTION OF THE DRAWINGS

FIG. 1 shows measured values of electric wiring resistance of wiring lines with Si₃N₄ oxidation inhibitor films and those of other wiring lines without the oxidation inhibitor films;

FIG. 2 is a schematic diagram of a TEM image of an oxidized tungsten wiring line;

FIG. 3 is a schematic diagram of a TEM image of a tungsten wiring line covered with a Si₃N₄ oxidation inhibitor film;

FIGS. 4A-4C are longitudinal sectional views for describing manufacturing steps of bit wiring lines of a related semiconductor device;

FIG. 5 shows film forming sequence of a related HDP-CVD method;

FIG. 6 is a pattern diagram of a W wiring line to which this invention is applied;

FIGS. 7A and 7B are longitudinal sectional views for describing manufacturing steps of bit wiring lines of a semiconductor device according to the preferred embodiment of this invention; and

FIG. 8 shows film forming sequence of an HDP-CVD method according to the embodiment of this invention.

### DESCRIPTION OF THE PREFERRED EMBODIMENTS

Referring to FIGS. 6 to 8, the description will be made about a dielectric film forming method according to a preferred embodiment of this invention.

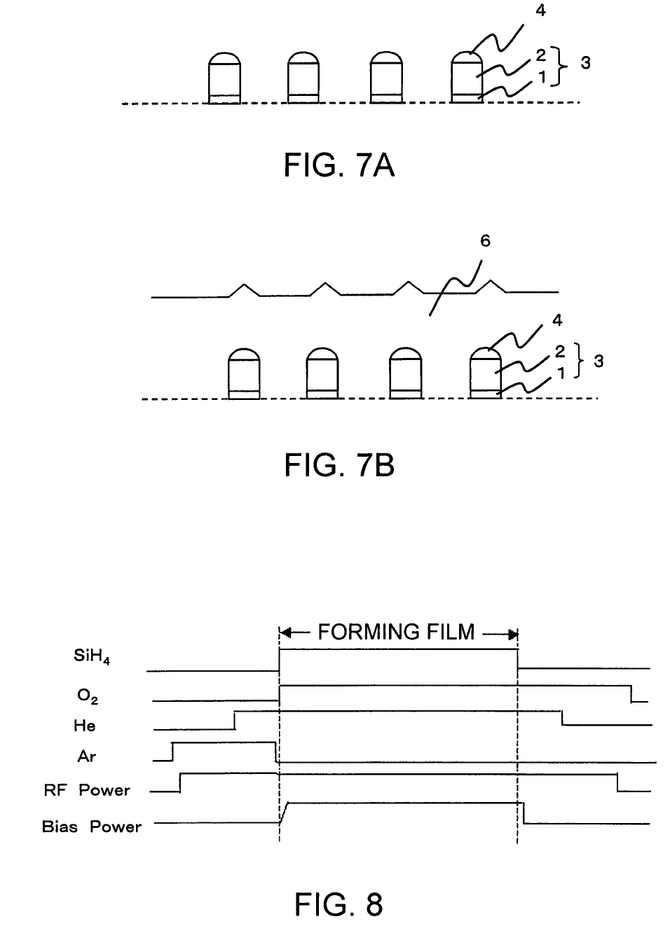

FIG. 6 is a pattern diagram of a tungsten (W) wiring line to which this invention is applied. FIGS. 7A and 7B are longitudinal sectional views for describing manufacturing steps of bit wiring lines of a semiconductor device according to the preferred embodiment. FIG. 8 shows film forming sequence of a high density plasma chemical vapor deposition (HDP-CVD) method according to the embodiment.

FIGS. 7A and 7B are the longitudinal sectional views for describing manufacturing steps of the bit wiring lines using W wiring lines of the invention. First, a tungsten nitride (WN) film 1, a tungsten (W) film 2 and a Si₃N₄ film mask 4 are formed on a semiconductor substrate in this order. After that, as illustrated in FIG. 7A, a photo resist and etching technique are used to form W wiring lines 3 each of which is made of the WN film 1 and the W film 2. Incidentally, a titanium nitride (TiN) film may be used as a substitute for the WN film 1.

Subsequently, as shown in FIG. 7B, an oxide film is formed on the semiconductor substrate to cover the W wiring lines 3. The oxide film is an HDP-CVD oxide film 6 formed by the HDP-CVD method and in contact with the W wiring lines 3 directly.

FIG. 8 shows film forming sequence of the HDP-CVD method according to the embodiment. To form the HDP-CVD oxide film 6, reactive or source gasses of silane (SiH₄) gas and oxygen (O₂) gas, and carrier gases (He, Ar) are used.

In the film forming sequence, first, argon (Ar) gas is introduced into a reactive chamber and then source power (RF power) is applied thereto to generate plasma. After that, the carrier gas (He) is introduced in to the reactive chamber. The semiconductor substrate is heated by plasma of the Ar and the He gasses and then introduction of the Ar gas is stopped. Subsequently, the SiH₄ gas and the O₂ gas are coincidently introduced into the reactive chamber and bias power is applied thereto. It is preferable that the bias power is gradually increased at the early stages. That is, it is preferable that the bias power is applied with ramping. The ramping is performed so that the bias power reaches a predetermined power between one and ten seconds. Preferably, the ramping is performed so that the bias power reaches the predetermined power between one to three seconds.

Regarding flow rates of the SiH₄ gas and the O₂ gas, similarly, it is preferable that they are gradually increased with ramping to suppress rapid pressure change in the reactive chamber.

Thus, the O₂ gas is not introduced into the reactive chamber before start of film formation (or introduction of the SiH₄ gas) in this embodiment. In other words, introduction of the O₂ gas is started when or after the introduction of the remaining reactive gas (i.e. SiH₄ gas) is started. Therefore, it is possible to suppress oxidation of the W wiring lines 3.

As mentioned above, in the film forming sequence according to the embodiment, the semiconductor substrate is heated by the plasma generated by the carrier gasses (Ar, He) and the RF power. After the introduction of the Ar gas is stopped, the SiH₄ gas and the O₂ gas are simultaneously introduced into the reactive chamber and the bias power is applied thereto with the ramping to form the oxide film.

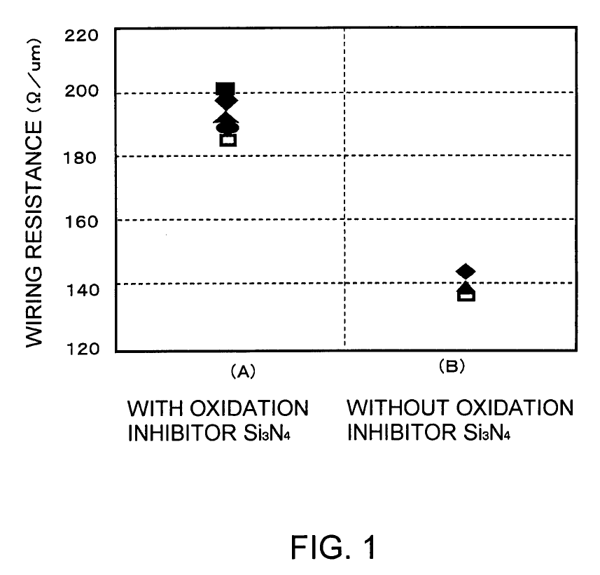

In the film forming sequence of the embodiment, because the oxygen environment gas is not introduced into the reactive chamber before start of film formation (or introduction of the SiH₄ gas), the oxidation of the W wiring lines 3 is suppressed. That is, the W wiring lines are not oxidized without Si₃N₄ film oxidation inhibitor. Accordingly, increase of electric wiring resistance caused by the Si₃N₄ film oxidation inhibitor can be prevented. Thus, low electric wiring resistance as shown at right hand side of FIG. 1 is obtained.

Referring to FIG. 1 again, values of electric wiring resistance of wiring lines with Si₃N₄ oxidation inhibitor films are plotted at the left hand side while those of other wiring lines without the oxidation inhibitor films are plotted at the right hand side. Each symbol designates a mean value of electric wiring resistance of wiring lines formed on a semiconductor wafer.

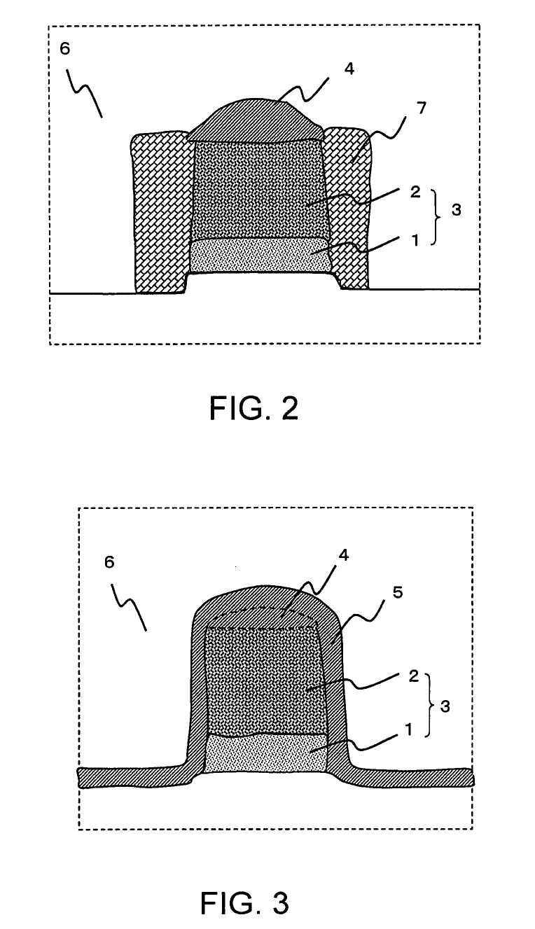

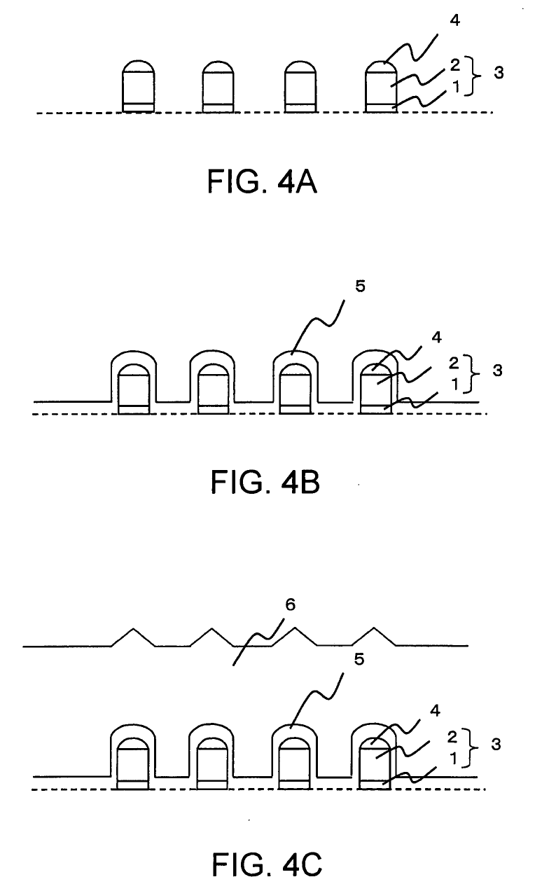

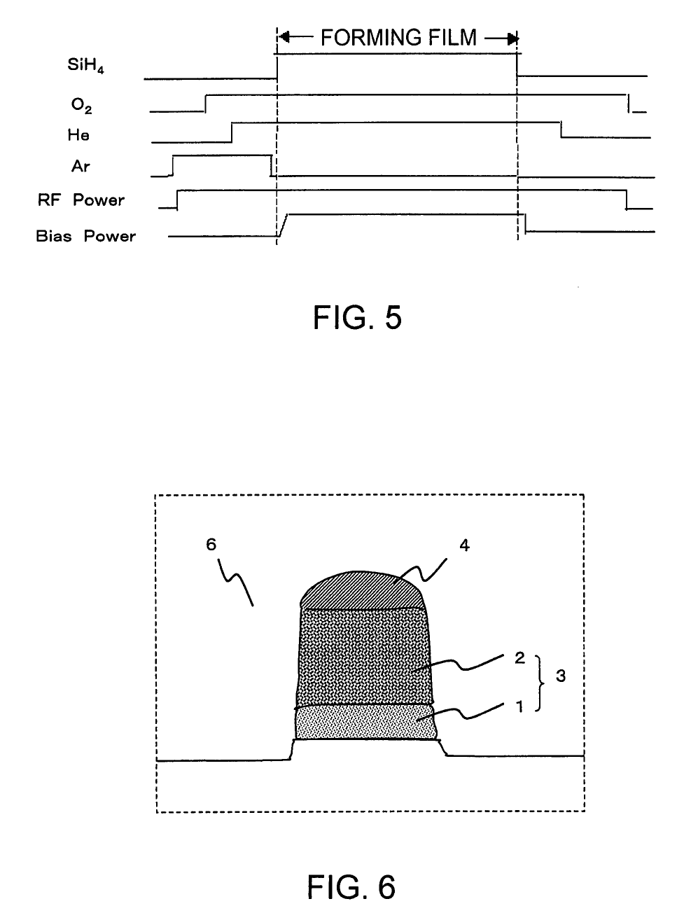

If the HDP-CVD oxide film is formed by the related film forming sequence as illustrated in FIG. 5, side surfaces of the W wiring lines are oxidized when the HDP-CVD oxide film is formed as shown in FIG. 2. Increase of the electric wiring resistance and peeling off of the W wiring lines are caused by the oxidization of the W wiring lines. To the contrary, as mentioned above, because the O₂ gas is not introduced into the reactive chamber before start of film formation (or introduction of the SiH₄ gas) in this embodiment, it is suppressed that the W wiring lines 3 is oxidized. Thus, oxidization of the side surfaces of the W wiring lines can be inhibited.

If the Si₃N₄ film oxidation inhibitor is used for the W wiring lines, the electric wring resistance is increased by 30 percents as compared with a case where the Si₃N₄ film oxidation inhibitor is not used, as illustrated in FIG. 1. And so it is required to increase thickness of the W wiring lines and thereby causing a problem that the miniaturization is impossible. By contrast, the film forming sequence of this embodiment can form the HDP-CVD oxidation film without oxidation of the W wiring lines even though the Si₃N₄ film is not used as the oxidation inhibitor for the W wiring lines. Furthermore, increase of the electric wiring resistance can be suppressed.

In the forming method of the HDP-CVD oxidation film according to the embodiment, the semiconductor substrate is heated by the plasma generated by the carrier gasses (Ar, He) and the RF power. After the introduction of the Ar gas is stopped, the SiH₄ gas and the O₂ gas are simultaneously introduced into the reactive chamber and the bias power is applied thereto with the ramping.

In the film forming sequence of the embodiment, because the oxygen environment gas is not introduced into the reactive chamber before start of film formation (or introduction of the SiH₄ gas), the oxidation of the W wiring lines 3 is suppressed. Because the oxidation of the W wiring lines are inhibited, the HDP-CVD oxidation film can be directly formed on the W wiring lines. By use of the HDP-CVD oxidation film formed by the film forming method of the embodiment, it is allowed that the W wiring lines have low electric resistance and microscopic fabrication. Furthermore, by use of the W wiring lines having the low electric resistance and the microscopic fabrication, a large scale integrated semiconductor device which can operate at high speed is obtained.

Although the present invention has been described based on its preferred embodiment with a certain degree of particularity, it is to be understood that the present invention is not limited to the embodiment but may be otherwise variously embodied within the scope and sprit of the invention. These modifications and variations should be considered to be within the scope of the invention. For example, though the W wiring lines are used as metal wiring lines in the embodiment, the metal wiring lines is not limited to the W wiring lines and the film forming sequence according to this invention can be applied to other metal films which are easy to be oxidized.

What is claimed is:

1. A film forming method for forming a dielectric film including oxygen by a plasma chemical vapor deposition method, comprising:
forming the dielectric film on a metal wiring line formed on a semiconductor substrate in a reactive chamber, wherein
gas including the oxygen is not introduced into the reactive chamber before the forming step.

2. A film forming method as claimed in claim 1, further comprising:
introducing a carrier gas into the reactive chamber before the forming step;
applying source power to the carrier gas to generate plasma and to heat the semiconductor substrate by the plasma;
introducing silane and oxygen into the reactive chamber as source gas for the dielectric film after the applying step of the source power; and
applying bias power to the source gas to execute the forming step.

3. A film forming method as claimed in claim 2, wherein the silane and oxygen are simultaneously introduced into the reactive chamber and then the bias power is supplied.

4. A film forming method as claimed in claim 2, wherein the silane and the oxygen are gradually increased with ramping to suppress rapid pressure change in the reactive chamber when the silane and the oxygen are simultaneously introduced into the reactive chamber.

5. A film forming method as claimed in claim 2, wherein the bias power is increased with ramping.

6. A film forming method as claimed in claim 5, wherein the ramping is performed for a period of between one and ten seconds.

7. A film forming method as claimed in claim 1, wherein the metal wiring line comprises high melting point metal.

8. A film forming method as claimed in claim 1, wherein the metal wiring line comprises tungsten.

9. A film forming method as claimed in claim 1, wherein the metal wiring line comprises tungsten and tungsten nitride.

10. A film forming method as claimed in claim 1, wherein the metal wiring line comprises tungsten and titanium nitride.

11. A semiconductor device comprising:
a metal wiring line formed on a semiconductor substrate; and
a dielectric film including oxygen formed on the metal wiring line, wherein
the dielectric film is formed in a reactive chamber by a plasma chemical vapor deposition method, and wherein
gas including the oxygen is not introduced into the reactive chamber before formation of the dielectric film.

12. A semiconductor device as claimed in claim 1, wherein the dielectric film is formed by the steps of:
introducing a carrier gas into the reactive chamber before the formation of the dielectric film;
applying source power to the carrier gas to generate plasma and to heat the semiconductor substrate by the plasma;
introducing silane and oxygen into the reactive chamber as source gas for the dielectric film after the applying step of the source power; and
applying bias power to the source gas to execute the formation of the dielectric film.

13. A semiconductor device as claimed in claim 12, wherein the silane and oxygen are simultaneously introduced into the reactive chamber and then the bias power is supplied.

14. A semiconductor device as claimed in claim 12, wherein the silane and the oxygen are gradually increased with ramping to suppress rapid pressure change in the reactive chamber when the silane and the oxygen are simultaneously introduced into the reactive chamber.

15. A semiconductor device as claimed in claim 12, wherein the bias power is increased with ramping.

16. A semiconductor device as claimed in claim 15, wherein the ramping is performed for a period of between one and ten seconds.

17. A semiconductor device as claimed in claim 11, wherein the metal wiring line comprises high melting point metal.

18. A semiconductor device as claimed in claim 11, wherein the metal wiring line comprises tungsten.

19. A semiconductor device as claimed in claim 11, wherein the metal wiring line comprises tungsten and tungsten nitride.

20. A semiconductor device as claimed in claim 11, wherein the metal wiring line comprises tungsten and titanium nitride.

21. A semiconductor device as claimed in claim 11, wherein the dielectric film is in contact with the metal wiring line directly.

22. A film forming method for forming a dielectric film including oxygen by plasma chemical vapor deposition method, comprising:
forming the dielectric film on a metal wiring line formed on a semiconductor substrate in a reactive chamber, wherein
introduction of gas including the oxygen into the reactive chamber is started to start the forming step.
